(19) United States
(12) Patent Application Publication
(10) Pub. No.: US 2023/0411355 A1
(43) Pub. Date: Dec. 21, 2023

(54) SEMICONDUCTOR PACKAGE AND METHOD OF MANUFACTURING THE SAME

(71) Applicant: Samsung Electronics Co., Ltd., Suwon-si (KR)

(72) Inventors: Yonghoe Cho, Suwon-si (KR); Eunkyoung Choi, Suwon-si (KR); Changeun Joo, Suwon-si (KR)

(21) Appl. No.: 18/138,564

(22) Filed: Apr. 24, 2023

(30) Foreign Application Priority Data
May 30, 2022 (KR) 10-2022-0065759

(51) Int. Cl. H01L 25/065; H01L 23/48; H01L 23/522; H01L 23/00; H01L 23/31; H10B 80/00

(52) U.S. Cl. CPC H01L 25/0657; H01L 2225/06513; H01L 23/5226; H01L 24/16; H01L 24/32; H01L 24/73; H01L 23/3107; H01L 23/3135; H01L 24/17; H01L 25/0652; H10B 80/00; H01L 2224/16145; H01L 2224/32145; H01L 2224/73204; H01L 2224/17181; H01L 2225/06568; H01L 23/481

(57) ABSTRACT

A semiconductor package includes a first semiconductor chip including a first interconnection structure on first surface, through-electrodes connected to the first interconnection structure, a redistribution structure on a second surface and connected to the through-electrodes, and first contact pads on the redistribution structure, a second semiconductor chip including a second interconnection structure, the second semiconductor chip having a first region on which the first semiconductor chip is disposed, and second contact pads on the first region and bonded to the first contact pads, first conductive posts on the first interconnection structure, a first mold layer on the first interconnection structure and surrounding the first conductive posts, second conductive posts on the second region, a second mold layer on the second region and surrounding the second conductive posts, the first semiconductor chip, and the first molded layer, and a passivation layer on the first molded layer and the second molded layer.

### CROSS-REFERENCE TO RELATED APPLICATION(S)

This application claims benefit of priority to Korean Patent Application No. 10-2022-0065759 filed on May 30, 2022 in the Korean Intellectual Property Office, the disclosure of which is herein incorporated by reference in its entirety.

### BACKGROUND

The present inventive concept relates to a semiconductor package and a method of manufacturing the same.

According to the requirements for high speed and a high degree of integration in semiconductor devices, a three-dimensional system-in-package (SIP) method in which semiconductor chips are directly connected with fine bumps has been developed. In particular, as the number of input/output pins dramatically increases due to the high degree of integration, connection technology using fine-pitch through-electrodes (e.g., through-silicon-vias, TSV) is desirable, and attempts to apply a semiconductor chip stacking structure using the same are spreading.

### SUMMARY

One of the technical problems to be solved by the present inventive concept is to provide a semiconductor package for preventing damage or deformation of a package substrate during a manufacturing process.

One of the technical problems to be solved by the present inventive concept is to provide a method of manufacturing a semiconductor package for preventing damage or deformation of a package substrate during a manufacturing process.

According to an aspect of the present disclosure, a semiconductor package includes a first semiconductor chip including a first semiconductor substrate having a first active surface and a first non-active surface, located opposite to each other, a first interconnection structure disposed on the first active surface, through-electrodes passing through the first semiconductor substrate and connected to the first interconnection structure, a redistribution structure disposed on the first non-active surface and connected to the through-electrodes, and first contact pads disposed on the redistribution structure; a second semiconductor chip including a second semiconductor substrate having a second active surface and a second non-active surface, located opposite to each other, a second interconnection structure disposed on the second active surface and having a first region on which the first semiconductor chip is disposed and a second region, different from the first region, and second contact pads disposed on the first region of the second interconnection structure and respectively bonded to the first contact pads; first conductive posts disposed on the first interconnection structure; a first mold layer disposed on the first interconnection structure and surrounding each of the first conductive posts; second conductive posts disposed on the second region of the second interconnection structure; a second mold layer disposed on the second region of the second interconnection structure and surrounding each of the second conductive posts, the first semiconductor chip, and the first molded layer; a passivation layer disposed on the first mold layer and the second mold layer; first conductive connection structures passing through the passivation layer and respectively connected to the first conductive posts; and second conductive connection structures passing through the passivation layer and respectively connected to the second conductive posts.

According to an aspect of the present disclosure, a semiconductor package includes a first semiconductor chip including a first substrate having a first surface and a second surface, located opposite to each other, and including a redistribution structure located on the first surface, a first interconnection structure disposed on the second surface, through-electrodes passing through the first substrate and connecting the redistribution structure to the first interconnection structure, and first contact pads disposed on the first interconnection structure; first conductive posts disposed on the first interconnection structure and electrically connected to the first interconnection structure; a first mold layer disposed on the first interconnection structure and having an upper surface, coplanar with upper ends of the first conductive posts; a second semiconductor chip including a second interconnection structure having a first region on which the first semiconductor chip is disposed and a second region, different from the first region, and second contact pads disposed on the first region of the second interconnection structure and respectively connected to the first contact pads, wherein the first surface of the first semiconductor chip is disposed to face the second interconnection structure; second conductive posts disposed on the second region of the second interconnection structure and electrically connected to the second interconnection structure; a second mold layer disposed on the second region of the second interconnection structure, and having an upper surface, coplanar with upper ends of the second conductive posts and the upper surface of the first mold layer; a passivation layer disposed on the first mold layer and the second mold layer; and a plurality of conductive connection structures passing through the passivation layer and respectively connected to the first and second conductive posts.

According to an aspect of the present disclosure, a semiconductor package includes a first semiconductor chip including a first substrate having a first surface and a second surface, located opposite to each other, and including a redistribution structure located on the first surface, a first interconnection structure disposed on the second surface, through-electrodes passing through the first substrate and connecting the redistribution structure to the first interconnection structure, and first contact pads disposed on the redistribution structure; first conductive posts disposed on the redistribution structure and electrically connected to the first interconnection structure; a first mold layer disposed on the redistribution structure and having an upper surface, coplanar with upper ends of the first conductive posts; a second semiconductor chip including a second interconnection structure having a first region on which the first semiconductor chip is disposed and a second region, different from the first region, and second contact pads disposed on the first region of the second interconnection structure and respectively connected to the first contact pads, wherein the second surface of the first semiconductor chip is disposed to face the second interconnection structure; second conductive posts are disposed on the second region of the second interconnection structure and are electrically connected to the second interconnection structure; a second mold layer is disposed on the second region of the second interconnection structure, and having an upper surface, coplanar with upper ends of the second conductive posts and the upper surface of the first mold layer; a passivation layer disposed on the first mold layer and the second mold layer; and a plurality of conductive connection structures passing through the passivation layer and respectively connected to the first and second conductive posts.

According to an aspect of the present disclosure, a method of manufacturing a semiconductor package includes preparing a first wafer having a first active surface on which a plurality of first semiconductor chips are implemented and a preliminary first non-active surface opposite to the first active surface, wherein each of the plurality of first semiconductor chips includes a first interconnection structure disposed on the first active surface of the first wafer, and through-electrodes extending from the first active surface toward the preliminary first non-active surface and connected to the first interconnection structure; forming first conductive posts and a first mold layer on the first interconnection structure, the first mold layer surrounding each of the first conductive posts; after forming the first mold layer, polishing the preliminary first non-active surface of the first wafer to form a first non-active surface of the first wafer, the through-electrodes being exposed at the first non-active surface of the first wafer; forming a redistribution structure connected to the through-electrodes on the first non-active surface of the first wafer, and forming first contact pads on the redistribution structure; after forming the first contact pads, cutting the first wafer into the plurality of first semiconductor chips; preparing a second wafer having a second active surface on which a plurality of second semiconductor chips are implemented, wherein each of the plurality of second semiconductor chips is disposed on the second active surface and includes a second interconnection structure having a first region and a second region, different from each other, and second contact pads disposed on the first region; forming second conductive posts on the second region of the second interconnection structure of each of the plurality of second semiconductor chips; mounting each of the plurality of first semiconductor chips on the first region of the second interconnection structure of a corresponding one of the plurality of second semiconductor chips, wherein the first contact pads are respectively bonded to the second contact pads; forming a second mold layer on the second interconnection structure of the second wafer to surround each of the plurality of first semiconductor chips, the first mold layer, and each of the second conductive posts; forming a passivation layer disposed on the first mold layer and the second mold layer; and forming a plurality of conductive connection structures passing through the passivation layer and respectively connected to the first and second conductive posts through the passivation layer.

According to an aspect of the present disclosure, a method of manufacturing a semiconductor package includes preparing a first wafer having a first active surface on which a plurality of first semiconductor chips are implemented and a preliminary first non-active surface opposite to the first active surface, wherein each of the plurality of first semiconductor chips includes a first interconnection structure disposed on the first active surface of the first wafer, and through-electrodes connected to the first interconnection structure; forming first contact pads on the first interconnection structure; after forming the first contact pads, polishing the preliminary first non-active surface of the first wafer to form a first non-active surface of the first wafer, the through-electrodes being exposed at the first non-active surface of the first wafer; forming a redistribution structure on the first non-active surface of the first wafer, the redistribution structure being connected to the through-electrodes; forming first conductive posts and a first mold layer on the redistribution structure, the first mold layer surrounding each of the first conductive posts; after forming the first conductive posts and the first mold layer, cutting the first wafer into the plurality of first semiconductor chips separated from each other; preparing a second wafer having a second active surface at which a plurality of second semiconductor chips are implemented, wherein each of the plurality of second semiconductor chips is disposed at the second active surface and includes a second interconnection structure having a first region and a second region, different from each other, and second contact pads disposed on the first region; forming second conductive posts on the second region of the second interconnection structure of each of the plurality of second semiconductor chips; mounting each of the plurality of first semiconductor chips on the first region of the second interconnection structure of a corresponding one of the plurality of second semiconductor chips, wherein the first contact pads are respectively bonded to the second contact pads; forming a second mold layer on the second interconnection structure of the second wafer to surround each of the plurality of first semiconductor chips, the first mold layer, and each of the second conductive posts; forming a passivation layer disposed on the first mold layer and the second mold layer, and forming a plurality of conductive connection structures passing through the passivation layer and respectively connected to the first and second conductive posts.

### BRIEF DESCRIPTION OF DRAWINGS

The above and other aspects, features, and advantages of the present inventive concept will be more clearly understood from the following detailed description, taken in conjunction with the accompanying drawings, in which:

FIG. 1 is a side cross-sectional view of a semiconductor package according to an embodiment.

FIGS. 2A to 2C are plan cross-sectional views of the semiconductor package illustrated in FIG. 1, taken along lines I1-I1′, I2-I2′, and I3-I3′, respectively.

FIG. 3 is a side cross-sectional view of a semiconductor package according to an embodiment.

FIGS. 4A to 4F are cross-sectional views for illustrating processes (for manufacturing a first semiconductor chip) in a method of manufacturing the semiconductor package illustrated in FIG. 1.

FIGS. 5A to 5F are cross-sectional views for illustrating processes (for manufacturing a final package) in a method of manufacturing the semiconductor package illustrated in FIG. 1.

FIGS. 6A to 6E are cross-sectional views for illustrating processes (for manufacturing a first semiconductor chip) in a method of manufacturing the semiconductor package illustrated in FIG. 3.

FIGS. 7A to 7D are cross-sectional views for illustrating processes (for manufacturing a final package) in a method of manufacturing the semiconductor package illustrated in FIG. 3.

FIG. 8 is a side cross-sectional view of a semiconductor package according to an embodiment.

FIG. 9 is a side cross-sectional view of a semiconductor package according to an embodiment, and FIG. 10 is a plan cross-sectional view of the semiconductor package of FIG. 9, taken along line II1-II1′.

FIG. 11 is a side cross-sectional view of a semiconductor package according to an embodiment, and FIG. 12 is a plan cross-sectional view of the semiconductor package of FIG. 11, taken along line II2-II2′.

FIG. 13 is a side cross-sectional view of a semiconductor package according to an embodiment.

FIG. 14 is a side cross-sectional view of a semiconductor package according to an embodiment.

### DETAILED DESCRIPTION

Hereinafter, various embodiments will be described in detail with reference to the accompanying drawings.

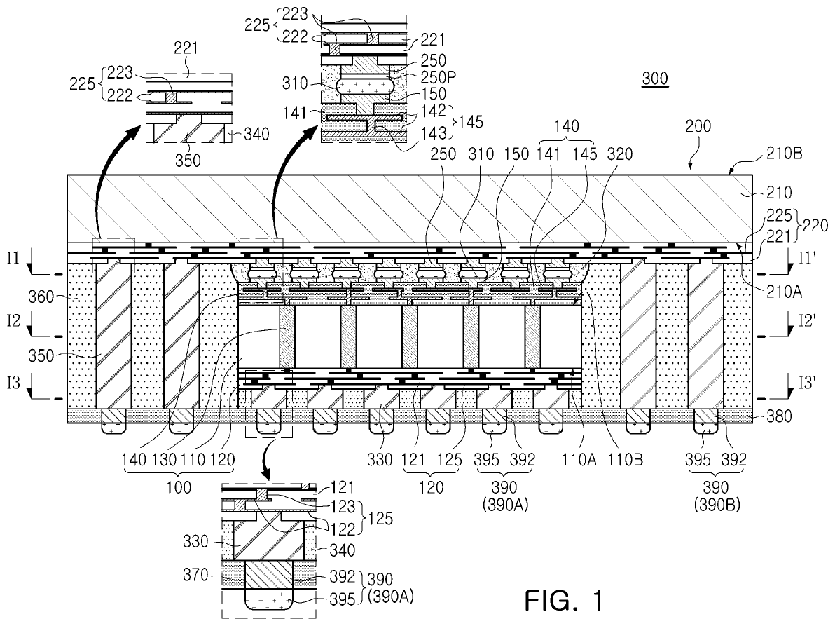

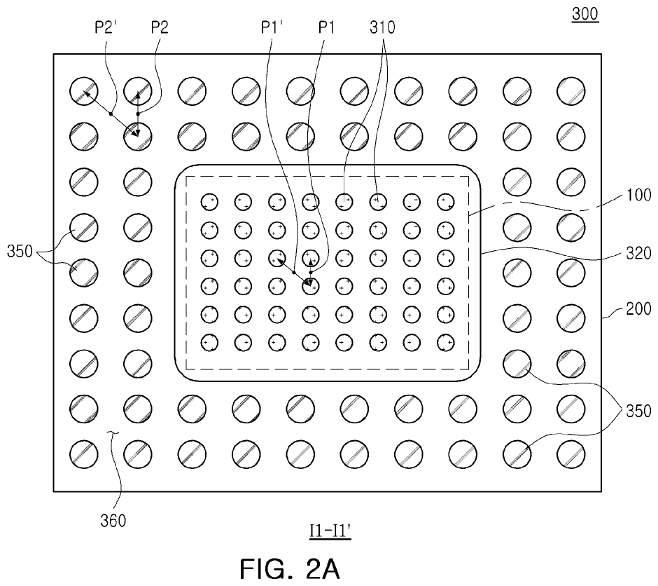

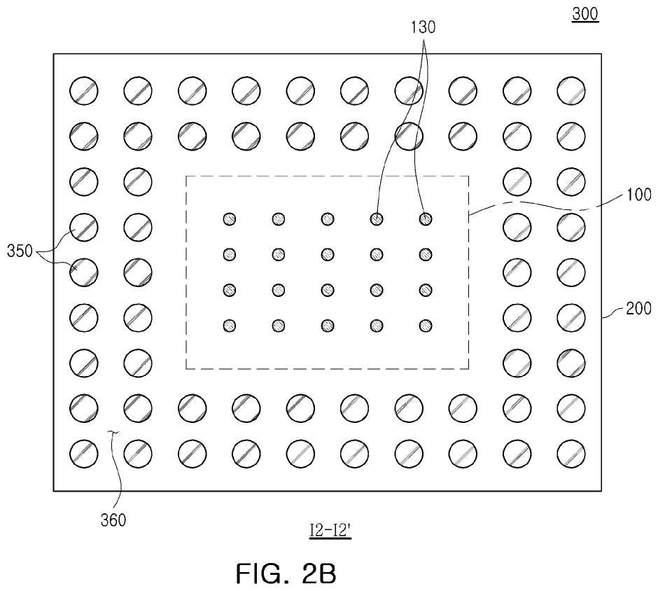

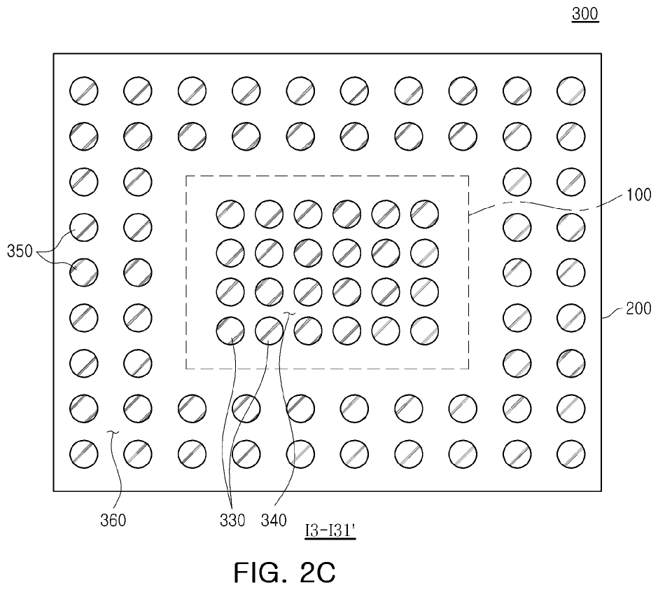

FIG. 1 is a side cross-sectional view of a semiconductor package according to an embodiment, and FIGS. 2A to 2C are plan cross-sectional views of the semiconductor package illustrated in FIG. 1, taken along lines I1-I1′, I2-I2′, and I3-I3′, respectively.

Referring to FIGS. 1 and 2A to 2C, a semiconductor package 300 according to the present embodiment has a first semiconductor chip 100 having a first area, and a second semiconductor chip 200 having a second area, larger than the first area, and on which the first semiconductor chip 100 is mounted. In this mounting structure, first contact pads 150 of the first semiconductor chip 100 may be respectively bonded to second contact pads 250 of the second semiconductor chip 200 by a conductive bump 310.

The first semiconductor chip 100 may include a first semiconductor substrate 110 having a first active surface 110A and a first non-active surface 110B, located opposite to each other, a first interconnection structure 120 disposed on the first active surface 110A, and through-electrodes 130 passing through the first semiconductor substrate 110 and connected to the first interconnection structure 120. In this specification, the first active surface 110A refers to a region of the first semiconductor substrate 110 in which a plurality of active/passive devices (e.g., transistors) are formed.

The first interconnection structure 120 may include a first interconnection layer 125 electrically connected to the devices, and the first interconnection layer 125 may be configured as a multilayer interconnection. The first interconnection structure 120 may include a first insulating layer 121 on which the first interconnection layer 125 is formed, and the first interconnection layer 125 may include first interconnection patterns 122, and interconnection vias 123 for interlayer connection.

The first semiconductor chip 100 employed in the present embodiment may include a redistribution structure 140 disposed on the first non-active surface 110B and connected to the through-electrodes 130. The redistribution structure 140 may include an insulating layer 141 and a redistribution layer 145 formed on the insulating layer 141, and the redistribution layer 145 may include redistribution patterns 142, and redistribution vias 143 for interlayer connection of the redistribution patterns 142. The first contact pads 150 of the first semiconductor chip 100 may be disposed on the redistribution structure 140, and may be electrically connected to the redistribution layer 145.

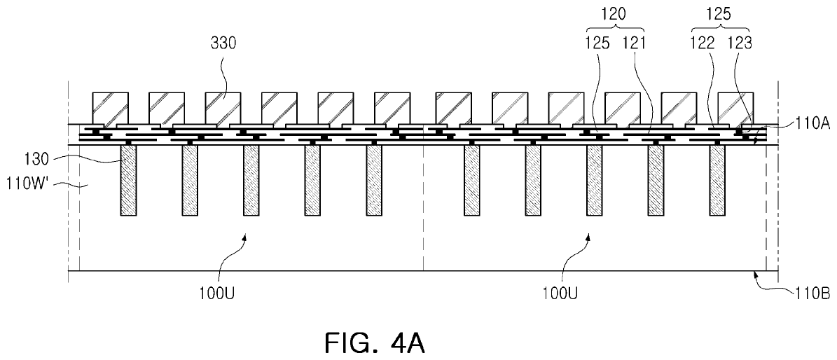

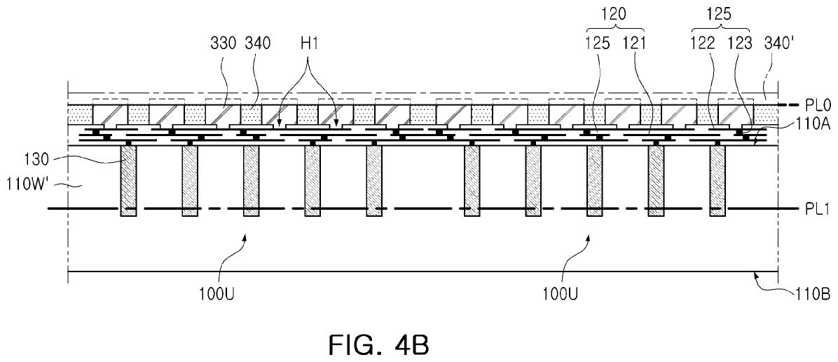

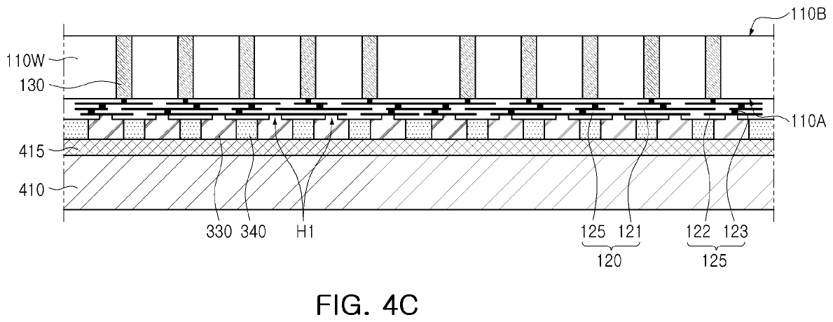

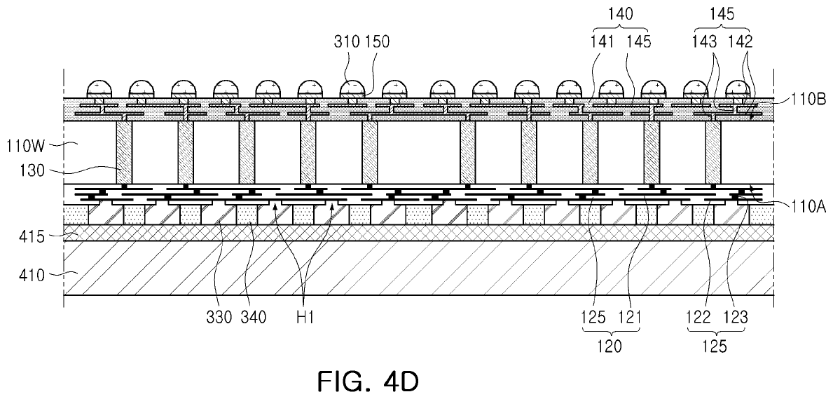

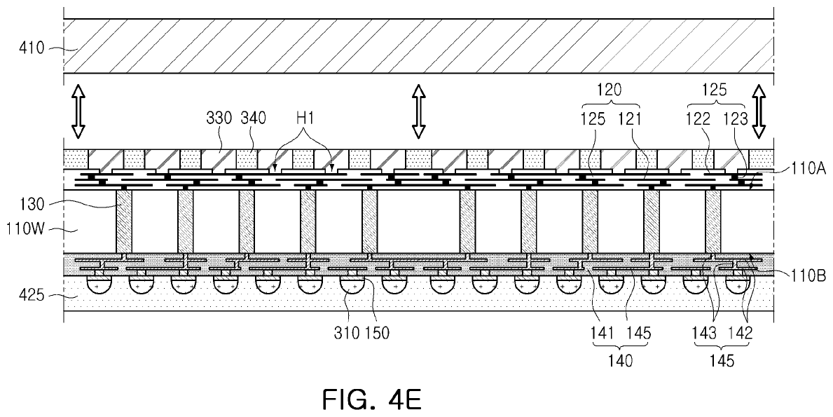

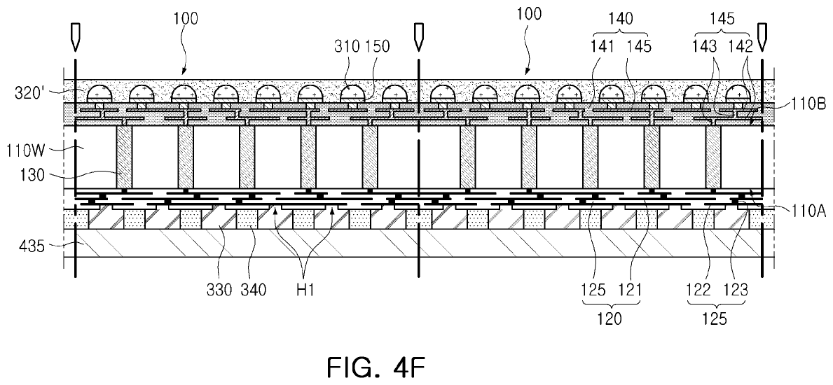

In the present embodiment, the redistribution structure 140 may be provided on one surface (e.g., the non-active surface 1101B) of the first semiconductor chip 100, and form a redistribution circuit for interconnection with the second semiconductor chip 200. Since the redistribution structure 140 may be formed in a wafer-level process of manufacturing the first semiconductor chip 100 (please refer to FIG. 4D), it may be more precisely formed on a surface having excellent flatness. The redistribution structure 140 may have an area corresponding to that of the first semiconductor chip 100. The redistribution structure 140 may have side surfaces, substantially coplanar with side surfaces of the first semiconductor chip 100, respectively. In an embodiment, the redistribution structure 140 and the first semiconductor chip 100, when viewed in a plan view, may have the same area. Terms such as “same,” “equal,” “planar,” or “coplanar,” as used herein encompass near identicality including variations that may occur, for example, due to manufacturing processes. The term “substantially” may be used herein to emphasize this meaning, unless the context or other statements indicate otherwise.

The second semiconductor chip 200 may include a second semiconductor substrate 210 having a second active surface 210A and a second non-active surface 210B, located opposite to each other, and a second interconnection structure 220 disposed on the second active surface 210A and having a first region on which the first semiconductor chip 100 is disposed and a second region, different from the first region. The second interconnection structure 220 may include a second interconnection layer 225 electrically connected to the second active surface 210A (e.g., devices), similarly to the first interconnection structure 120 as described above, and the second interconnection layer 225 may be configured as a multilayer interconnection. The second interconnection structure 220 may include a second insulating layer 221 on which the second interconnection layer 225 is formed, and the second interconnection layer 225 may include second interconnection patterns 222, and interconnection vias 223 for interlayer connection.

In the present embodiment, the second region may be disposed to surround the first region at which the first semiconductor chip 100 is disposed (refer to FIGS. 2A to 2C). The second contact pads 250 may be arranged in the first region of the second interconnection structure 220, e.g., a region on which the first semiconductor chip 100 is mounted.

In the present embodiment, the redistribution structure 140 (or the first non-active surface 110B) of the first semiconductor chip 100 and the second interconnection structure 220 of the second semiconductor chip 200 may be mounted on each other. As described above, the first and second contact pads 150 and 250 may be bonded with each other by the conductive bumps 310, to ensure signal transmission between the first and second semiconductor chips 100 and 200. A non-conductive film 320 (i.e., an insulating film) may be disposed between the first semiconductor chip 100 and the second semiconductor chip 200, and may be formed to surround each of the conductive bumps 310. In an embodiment, the non-conductive film 320 may fill a space between the redistribution structure 140 and the second interconnection structure 220. The non-conductive film 320 may extend horizontally beyond the side surfaces of the first semiconductor chip 100. The non-conductive film 320 is also referred as an insulating adhesive layer. For example, the non-conductive film 320 may include an insulating polymer such as an epoxy resin.

The first semiconductor chip 100 may include first conductive posts 330 disposed on the first interconnection structure 120, and a first molded layer 340 (i.e., a first mold layer) disposed on the first interconnection structure 120 and surrounding each of the first conductive posts 330. Each of the first conductive posts 330 may be a pillar structure connected to the first interconnection layer 125 of the first interconnection structure 120 and having a predetermined height. For example, each of the first conductive posts 330 may include or may be formed of a conductive material such as copper (Cu) and aluminum (Al).

The first molded layer 340 may have an upper surface, substantially coplanar with upper ends of the first conductive posts 330. In an embodiment, the upper surface of the first molded layer 340 may refer to a surface of the first molded layer 340 adjacent to a plane at which solder balls 395 are disposed, and the upper ends of the first conductive posts 330 may refer to ends of the first conductive posts 330 adjacent to the plane at which the solder balls 395 are disposed. Using the solder balls 395, the semiconductor package 300 may be connected to an external device such as a main board (e.g., a motherboard) in an electronic device. For example, the semiconductor package 300 may be mounted on the main board in a face-down manner. For example, the first molded layer 340 may include or may be formed of an insulating resin such as epoxy molding compound (EMC). In some embodiments, the first conductive posts 330 and the first molded layer 340 may be formed in a wafer-level process of manufacturing the first semiconductor chip 100, similarly to the redistribution structure 140, as described above (see FIG. 4B). The first molded layer 340 may be cut, together with the first semiconductor chip 100, to be singulated. The first molded layer 340 may have side surfaces, coplanar with side surfaces of the first semiconductor chip 100.

Second conductive posts 350 may be disposed on the second region of the second interconnection structure 220. The second conductive posts 350 may be respectively connected to the second interconnection layer 225 of the second interconnection structure 220, to be provided as an input/output (I/O) signal connection path for the second semiconductor chip 200. As illustrated in FIGS. 2A to 2C, the second conductive posts 350 may be arranged to have relatively wide pitches P2 and P2′ in a region of the second semiconductor chip 200 around the first semiconductor chip 100, e.g., in the second region of the second interconnection structure 220. Referring to FIG. 2A, the conductive bumps 310 (e.g., the first and second contact pads) may be arranged to have narrower pitches P1 and P1′ than the pitches P2 and P2′ of the second conductive posts 350, and may have a relatively small area, respectively. Referring to FIG. 2C, the first conductive posts 330 may be arranged to have pitches, narrower than the pitches P2 and P2′ of the second conductive posts 350. In an embodiment, the second conductive posts 350 may be horizontally spaced apart from each other at a first pitch (e.g., P2 or P2′), and the conductive bumps 310 may be horizontally spaced apart from each other at a second pitch (e.g., P1 or P1′). The first pitch may be greater than the second pitch. In an embodiment, each of the second conductive posts 350 may be greater than each of the second conductive posts 330 in width.

The second conductive posts 350 may have a pillar structure, similar to that of the first conductive posts 330, but may be formed to have a height, higher than a height of the first conductive posts 330. Levels of upper ends of the second conductive posts 350 may be equal to levels of upper ends of the first conductive posts.

A second molded layer 360 may be disposed on the second region of the second interconnection structure 220, and may be formed to surround the first semiconductor chip 100 and each of the second conductive posts 350. As illustrated in FIG. 1, the second molded layer 360 may have an upper surface, substantially coplanar with the upper ends of the second conductive posts 350, and the upper surface of the second molded layer 360 may also be substantially coplanar with an upper surface of the molded layer 340 and the upper ends of the first conductive posts 330.

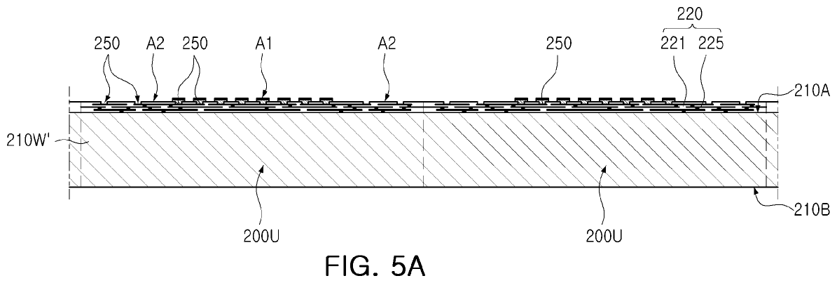

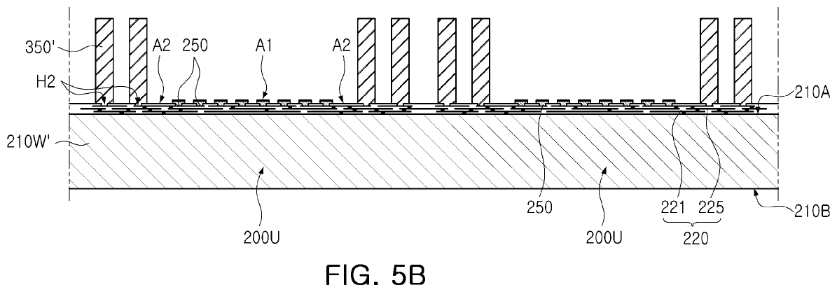

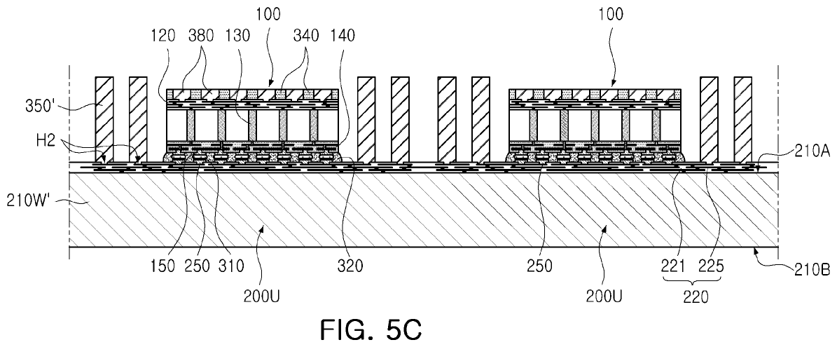

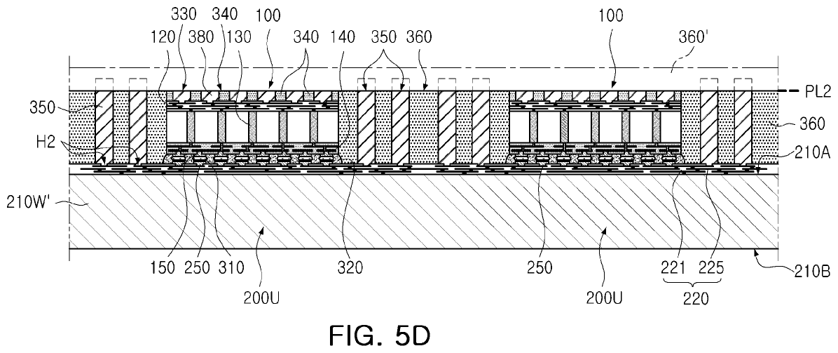

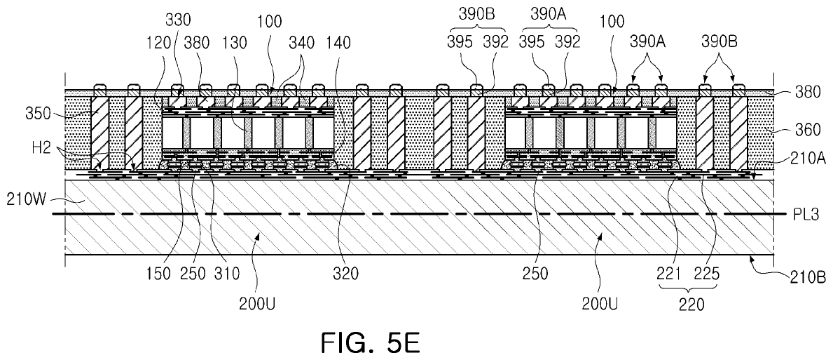

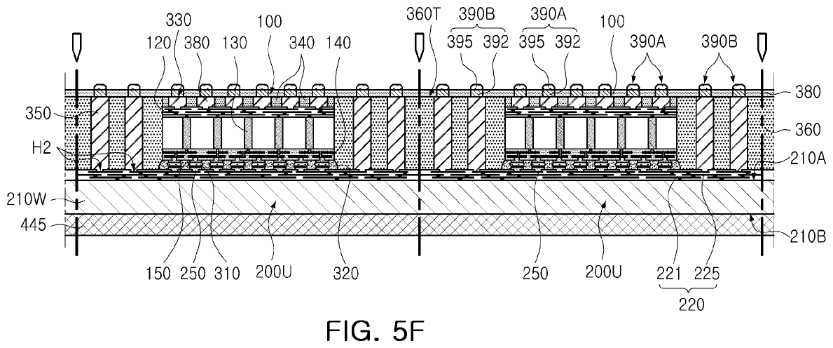

For example, similarly to the first conductive posts 330, each of the second conductive posts 350 may include or may be formed of a conductive material such as copper (Cu) and aluminum (Al). For example, the second molded layer 360 may include or may be formed of an insulating resin such as EMC, similarly to the first molded layer 340. Since the second molded layer 360 may be cut together with the second semiconductor chip 200 to be singulated (refer to FIG. 5F), the second molded layer 360 may have side surfaces, coplanar with side surfaces of the second semiconductor chip 200.

In some embodiments, since the first molded layer 340 and the second molded layer 360 may be formed by different processes, they may be formed of different insulating materials. In some embodiments, the first molded layer 340 and the second molded layer 360 may be formed of the same material such as EMC. Even though the first molded layer 340 and the second molded layer 360 are formed of the same material, since they may be formed by different processes or in separate processes, an interface between the first molded layer 340 and the second molded layer 360 may exist or may be visually identified.

The semiconductor package 300 according to the present embodiment may include a passivation layer 380 disposed on the first molded layer 340 and the second molded layer 360, and conductive connection structures 390 passing through the passivation layer 380 and respectively connected to the first and second conductive posts 330 and 350. The conductive connection structure 390 may serve to physically and/or electrically connect the semiconductor package 300 to an external circuit such as a main board of an electronic device. Each of the conductive connection structures 390 may include or may be a solder such as a low-melting-point metal, for example, tin (Sn)-aluminum (Al)-copper (Cu) or the like.

In the present embodiment, the conductive connection structure 390 may include a conductive pillar 392 such as a Cu pillar passing through the passivation layer 380, and a solder ball 395 disposed on the conductive pillar 392. In some embodiments, instead of the conductive pillar 392, an under bump metallurgy (UBM) layer may be formed. The solder ball 395 may be connected to an external circuit such as a main board of an electronic device.

In particular, in the present embodiment, the conductive connection structure 390 may include first conductive connection structures 390A respectively connected to the first conductive posts 330, and second conductive connection structures 390B respectively connected to the second conductive posts 350. As illustrated in FIG. 1, the passivation layer 380 may be formed to contact the upper surfaces of the first and second molded layers 340 and 360 without introducing an additional redistribution structure such as a redistribution layer (e.g., RDL). The first and second conductive connection structures 390A and 390B may be disposed in a one-to-one corresponding manner, in a region overlapping the first and second conductive posts 330 and 350, respectively. In an embodiment, the first conductive connection structures 390A may be connected to the first conductive posts 330, respectively, and the second conductive connection structures 390B may be connected to the second conductive posts 350, respectively. In an embodiment, each of the first conductive connection structures 390A may vertically overlap a corresponding one of the first conductive posts 330, and each of the second conductive connection structures 390B may vertically overlap a corresponding one of the second conductive posts 350. The term “contact,” as used herein, refers to a direct connection (i.e., touching) unless the context indicates otherwise.

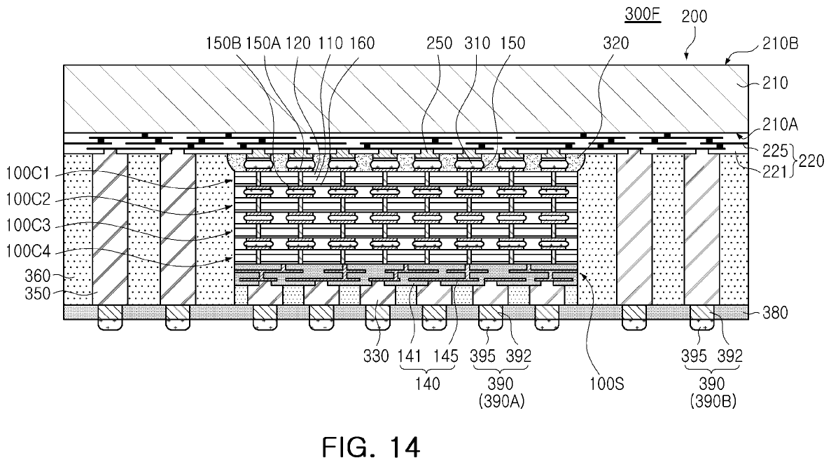

In some embodiments, the first and second semiconductor chips 100 and 200 may be a processor chip or a memory chip. For example, the first and second semiconductor chips 100 and 200 may be one of a microprocessor, a graphic processor, a signal processor, a network processor, a chipset, an audio codec, a video codec, an application processor, and a system-on-chip, and may be a processor chip in which some functions of a single chip are separated, but the present inventive concept is not limited thereto. In some embodiments, the first semiconductor chip 100 may be a volatile memory chip and/or a non-volatile memory chip, and the second semiconductor chip 200 “ay b’ a control chip for driving a memory device (see FIG. 14).

In the present embodiment, the first semiconductor chip 100 may be configured to face the active surface 110A serving as a main heat source in a downward direction. Therefore, since the first semiconductor chip 100 is disposed such that the active surface 110A does not face the active surface of the second semiconductor chip 200, which may be another main heat source, it is possible to prevent structural degradation in performance due to thermal confinement, and heat generated from the first semiconductor chip 100 may be effectively dissipated externally through the first conductive posts 330 and the first conductive connection structure 390A. In an embodiment, the first semiconductor chip 100 and the second semiconductor chip 200 may be mounted on a main board in a face down manner. For example, the first active surface 110A of the first semiconductor chip 100 and the second active surface 210A of the second semiconductor chip 200 face toward a plane where solder balls 395 arranged. The solder balls 395 may be connected to the main board.

As described above, since the semiconductor package 300 according to the present embodiment may secure a smooth heat dissipation path (particularly, the first semiconductor chip), performance and reliability of the first and second semiconductor chips 100 and 200 may be guaranteed.

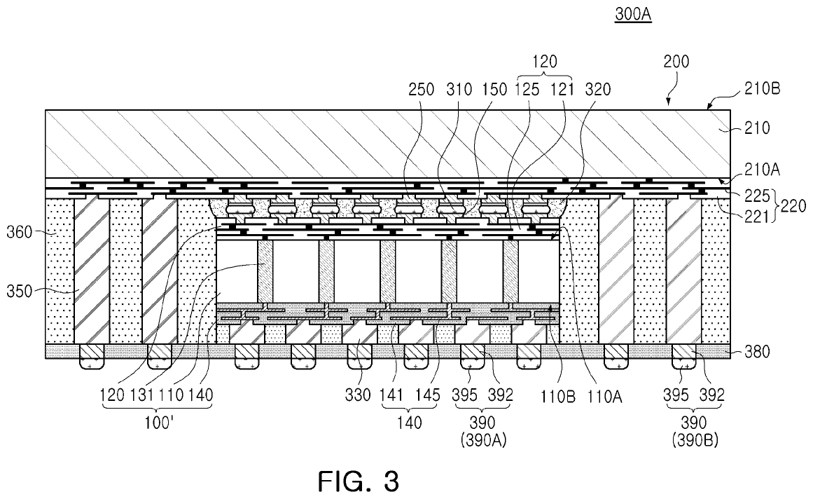

FIG. 3 is a side cross-sectional view of a semiconductor package according to an embodiment.

Referring to FIG. 3, it can be understood that a semiconductor package 300A according to the present embodiment is similar to the embodiment illustrated in FIGS. 1 and 2A to 2C, except that the first semiconductor chip 100 is vertically inverted. The inverted first semiconductor chip 100 may be referred to as a first semiconductor chip 100′. A redistribution structure 140 of a first semiconductor chip 100′ is disposed closer to a second semiconductor chip 200 than a first interconnection structure 120, first contact pads 150 are formed on the first interconnection structure 120 of the first semiconductor chip 100′, and first conductive posts 330 and a first molded layer 340 are formed on the redistribution structure 140. Therefore, the description of the embodiment illustrated in FIGS. 1 and 2A to 2C may be combined with description of the present embodiment unless otherwise specifically stated.

The first semiconductor chip 100′ employed in the present embodiment may be mounted on the second semiconductor chip 200 in a state vertically inverted from the first semiconductor chip 100 of the previous embodiment.

Specifically, as illustrated in FIG. 3, the first semiconductor chip 100′ may be mounted on a region of a second interconnection structure 220 such that a first active surface 110A of a first semiconductor substrate 110 faces the second semiconductor chip 200. The redistribution structure 140 of the first semiconductor chip 100, e.g., a first non-active surface 110B may be disposed farther from a lower surface of the semiconductor package 300A than the first interconnection structure 120.

The first contact pads 150 may be disposed on the first interconnection structure 120 of the first semiconductor chip 100′ to be connected to a first interconnection layer 125, and may be connected to second contact pads 250 of the second semiconductor chip 200 by conductive bumps 310, respectively. The first conductive posts 330 and the first molded layer 340 may be formed on the redistribution structure 140 facing the lower surface of the semiconductor package 300A. In this case, the first conductive posts 330 may be formed to be connected to a redistribution layer 145.

The semiconductor package 300A according to the present embodiment may be usefully applied when the number of signal terminals between the first and second semiconductor chips 100 and 200 increases, or a high signal transmission speed is desirable, even though heat dissipation performance is slightly lowered, compared to the previous embodiment.

FIGS. 4A to 4F are cross-sectional views for illustrating processes (for manufacturing a first semiconductor chip) in a method of manufacturing the semiconductor package illustrated in FIG. 1. These processes can be understood as processes for manufacturing the first semiconductor chip 100 employed in the semiconductor package 300 illustrated in FIG. 1.

Referring to FIG. 4A, first conductive posts 330 may be formed on a first interconnection structure 120 of a first wafer 110W′ at which a plurality of first semiconductor chips 100U are implemented.

The first wafer 110W′ may have a first active surface 110A at which devices for the plurality of first semiconductor chips 100U are implemented, and a first non-active surface 110B opposite to the first active surface 110A. Through-electrodes 130 connected to the first interconnection structure 120 may be formed at the first active surface 110A of the first wafer 110W′ using a plating process. In a plating process, a metal layer may grow from the first active surface 110A which serves as a seed layer to form the through-electrodes 130. The first interconnection structure 120 having a first interconnection layer 125 may be formed on the first active surface 110A of the first wafer 110W′, and the first interconnection layer 125 may be connected to the through-electrodes 130, respectively. The first through-electrodes 130 and the first interconnection structure 120 (in particular, the first interconnection layer 125) may be repeatedly arranged on the first wafer 110W′ in the same manner in a unit region for the plurality of first semiconductor chips 100U. Such a unit region may be cut into a separated first semiconductor chip. Next, the first conductive posts 330 may be formed on the first interconnection structure 120. For example, an opening may be formed in a first insulating layer 121 to expose a region of the first interconnection layer 125 (a partial region of a first interconnection pattern 122), and the first conductive posts 330 may be formed at the exposed region using a plating process.

Next, referring to FIG. 4B, a first molded layer 340 surrounding each of the first conductive posts 330 may be formed on the first interconnection structure 120.

A first molding member 340′ may be formed on the first interconnection structure 120 to cover the first conductive posts 330, and then the first molding member 340′ may be planarized to expose the first conductive posts 330, to form the first molded layer 340 having an upper surface, substantially coplanar with upper ends of the first conductive posts 330. For example, the first molding member 340′ may include or may be formed of an insulating resin such as EMC.

Next, referring to FIG. 4C, after the first wafer 110W′ is transferred onto a carrier substrate 410, a polishing process may be performed on the non-active surface 110B of the first wafer 110W′.

After the first wafer 110W′ is transferred to the carrier substrate 410 using an adhesive layer 415, a polishing process of the first wafer 110W′ may be performed. A desired thickness of the first wafer 110W′ may be reduced by performing the polishing process up to line PL1 illustrated in FIG. 4B, and one end of the through-electrodes 130 may be exposed from the non-active surface 110B of the first wafer 110W′. Such a polishing process may be performed by a chemical mechanical polishing (CMP) process. In some embodiments, the polishing process may be performed by an etch-back process. In some embodiments, a rear protective layer (not illustrated) at which one end of the through-electrodes 130 is exposed may be formed on a polished surface.

Next, referring to FIG. 4D, a redistribution structure 140 connected to the through-electrodes 130 may be formed on the polished surface of the first wafer 110W, and first contact pads 150 may be formed on the redistribution structure 140.

The redistribution structure 140 may include a plurality of insulating layers 141, and a redistribution layer 145 disposed on the plurality of insulating layers 141 and connected to each of the through-electrodes 130. In an embodiment, the redistribution layer 145 may be formed in a multi-level structure. At each level of the multi-level structure, after the insulating layer 141 is formed, a hole may be formed in a via formation position in the insulating layer 141, and the redistribution layer 145 in which a redistribution pattern 142 and a redistribution via 143 are integrated by the same plating process may be formed. A desired redistribution structure 140 may be formed by repeating such a series of processes as many as the number of layers in the multi-level structure. The redistribution layer 145 may include or may be formed of a conductive material, such as copper (Cu), aluminum (Al), silver (Ag), tin (Sn), gold (Au), nickel (Ni), lead (Pb), titanium (Ti), and an alloy thereof. After an opening for opening a partial region of an uppermost redistribution via 143 is formed in an uppermost insulating layer 141, the first contact pads 150 may be formed using a plating process, to be connected to the redistribution layer 145. Additionally, conductive bumps 310 for bonding to the second semiconductor chip 200 may be formed on the first contact pads 150, respectively.

Next, referring to FIG. 4E, after attaching a first adhesive film 425 to a surface of the first wafer 110W on which the first contact pads 150 are formed, the carrier substrate 410 may be detached from the first wafer 110W. Referring to FIG. 4F, after attaching the first wafer 110W to a second adhesive film 435 and removing the first adhesive film 425, the first wafer 110W may be cut into the plurality of first semiconductor chips 100. Before the cutting process, a non-conductive film 320 may be applied on a surface of the redistribution structure 140 on which the first contact pads 150 are formed, to cover the conductive bumps 310.

FIGS. 5A to 5F are cross-sectional views for illustrating processes (for manufacturing a final package) in a method of manufacturing the semiconductor package illustrated in FIG. 1. These processes can be understood as processes for manufacturing the semiconductor package 300 illustrated in FIG. 1 using the first semiconductor chip 100 manufactured by the process of FIG. 4F.

Referring to FIG. 5A, a second wafer 210W′ at which a plurality of second semiconductor chips 200U are implemented may be prepared.

The second wafer 210W′ may have a second active surface 210A at which devices for the plurality of second semiconductor chips 200U are implemented, and a second non-active surface 210B opposite to the second active surface 210A. A second interconnection structure 220 having a second interconnection layer 225 may be formed on the second active surface 210A of the second wafer 210W′, and the second interconnection layer 225 may be connected to the second active surface 210A (especially devices). Next, second contact pads 250 may be formed on a first region A1 of the second interconnection structure 220. For example, an opening may be formed in a second insulating layer 221 to expose a region of the second interconnection layer 225 (a partially expose the second interconnection pattern 222), and the second contact pads 250 may be formed at the exposed region using a plating process. In this case, a first semiconductor chip 100 may be mounted on the first region A1, and second conductive posts (350′ of FIG. 5B) for connecting I/O signals of a second semiconductor chip 200 in a second region A2 may be formed. In the present embodiment, although the second region A2 is illustrated as an example surrounding the first region A1 (see FIGS. 2A to 2C), the present inventive concept is not limited thereto, and the first region A1 may be located in a region adjacent to a corner.

Next, referring to FIG. 5B, second conductive posts 350 may be formed on the second region A2 of the second interconnection structure 220.

The second conductive posts 350 may be formed to be connected to the second interconnection layer 225 of the second interconnection structure 220. For example, an opening may be formed in the second insulating layer 221 to expose a region of the second interconnection layer 225 (a partial region of the second interconnection pattern 222), and the second conductive posts 350 may be formed at the exposed region using a plating process. The second conductive posts 350 may be formed to have a sufficient height. For example, the second conductive posts 350 may be formed to have at least a height, similar to a height of an upper surface of the first semiconductor chip 100.

Next, referring to FIG. 5C, a plurality of first semiconductor chips 100 may be respectively mounted on the first region A1 of the second interconnection structure 220.

The plurality of first semiconductor chips 100 may be obtained after a process described with reference to FIG. 4F. In the mounting process according to the present process, when a constant pressure is applied, conductive bumps 310 may pass through a non-conductive film 320, to be connected to the second contact pads 250, and first contact pads 150 may be bonded to the second contact pads 250 by the conductive bumps 310, respectively. Then, the non-conductive film 320 may be cured. The cured non-conductive film 320 may serve to protect the conductive bumps 310 between the first and second semiconductor chips 100 and 200. In this process, the first conductive posts 330 of the first semiconductor chips 100 may be disposed to face upward.

Next, referring to FIG. 5D, a second molded layer 360 may be formed on the second interconnection structure 220. The second molded layer 360 may surround a first molded layer 340, each of the second conductive posts 350, and each of the plurality of first semiconductor chips 100.

The present process may be performed by forming a second molding member 360′ on the second interconnection structure 220 to cover the first molded layer 340 and the second conductive posts 350, and then planarizing the second molding member 360′ to expose the first and second conductive posts 330 and 350. The second molded layer 360 thus obtained may have an upper surface, substantially coplanar with upper ends of the second conductive posts 350, and the upper surface of the second molded layer 360 may be substantially coplanar with an upper surface of the first molded layer 340 and upper ends of the first conductive posts 330. In some embodiments, the second molded layer 360 may be formed of an insulating material, different from that of the first molded layer 340. Even though the second molded layer 360 is formed of the same material as the first molded layer 340, since they may be formed by a different process or in separate processes, an interface between the first molded layer 340 and the second molded layer 360 may exist and may be visually identified.

Next, referring to FIG. 5E, a passivation layer 380 disposed on the first molded layer 340 and the second molded layer 360 may be formed, and a plurality of conductive connection structures 390 respectively connected to the second conductive posts 330 and 350 through the passivation layer 380 may be formed. Next, referring to FIG. 5F, after attaching to a third adhesive film 445, a cutting process may be performed to obtain a plurality of semiconductor packages 300.

In the present embodiment, the passivation layer 380 may be formed on the upper surfaces of the first and second molded layers 340 and 360 without introducing an additional redistribution structure. Therefore, first and second conductive connection structures 390A and 390B may be provided in a one-to-one corresponding manner, in a region overlapping the first and second conductive posts 330 and 350, respectively. In an embodiment, the first conductive connection structures 390A may be connected to the first conductive posts 330, respectively, and the second conductive connection structures 390B may be connected to the second conductive posts 350, respectively. In an embodiment, each of the first conductive connection structures 390A may vertically overlap a corresponding one of the first conductive posts 330, and each of the second conductive connection structures 390B may vertically overlap a corresponding one of the second conductive posts 350.

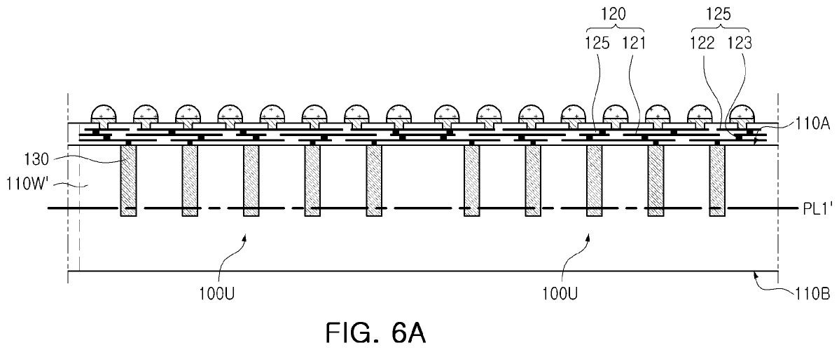

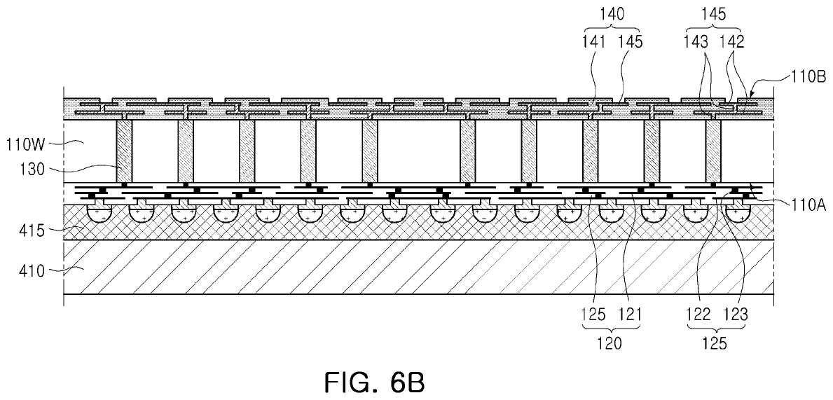

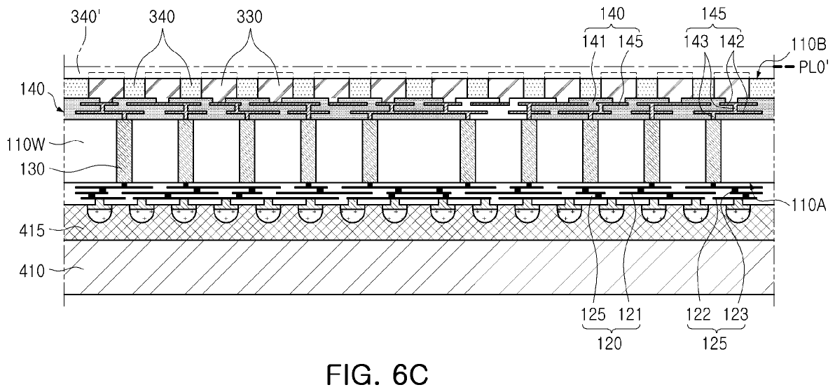

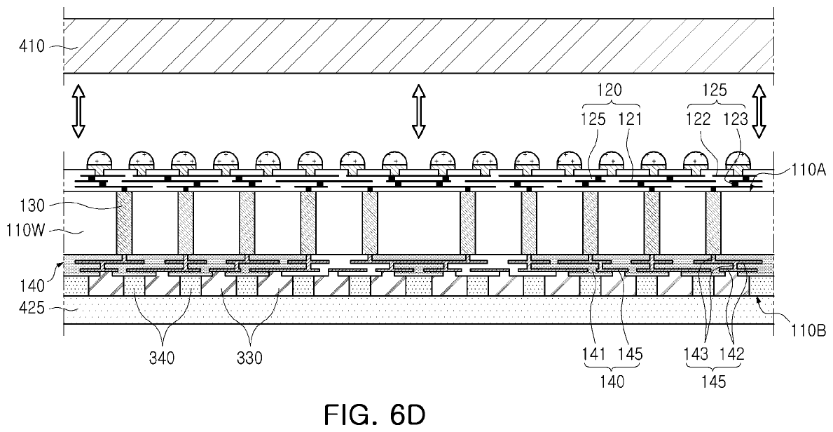

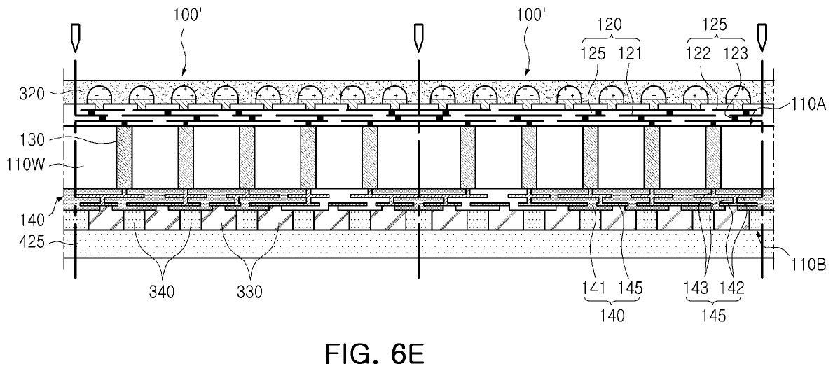

FIGS. 6A to 6E are cross-sectional views for illustrating processes (for manufacturing a first semiconductor chip) in a method of manufacturing the semiconductor package illustrated in FIG. 3. These processes can be understood as processes for manufacturing the first semiconductor chip 100′ employed in the semiconductor package 300A illustrated in FIG. 3.

Referring to FIG. 6A, first contact pads 150 may be formed on a first interconnection structure 120 of a first wafer 110W′ at which a plurality of first semiconductor chips 100U are implemented.

The first wafer 110W′ may have a first active surface 110A at which devices for the plurality of first semiconductor chips 100U are implemented, and a first non-active surface 110B opposite to the first active surface 110A. Through-electrodes 130 connected to the first interconnection structure 120 may be formed at the first active surface 110A of the first wafer 110W′. The first interconnection structure 120 having a first interconnection layer 125 may be formed on the first active surface 110A of the first wafer 110W′, and the first interconnection layer 125 may be connected to the through-electrodes 130, respectively. The first through-electrodes 130 and the first interconnection structure 120 (in particular, the first interconnection layer 125) may be repeatedly arranged on the first wafer 110W′ in the same manner in a unit region for the plurality of first semiconductor chips 100U. Such a unit region may be cut into a separate first semiconductor chip. Next, the first contact pads 150 may be formed to be connected to the first interconnection layer. For example, after an opening for opening a partial region of an uppermost redistribution via 143 may be formed in an uppermost insulating layer 141, the first contact pads 150 may be connected to a redistribution layer 145 using a plating process. Additionally, conductive bumps 310 for bonding to a second semiconductor chip 200 may be formed on the first contact pads 150, respectively.

Next, referring to FIG. 6B, after the first wafer 110W is transferred onto a carrier substrate 410, a polishing process may be performed on the non-active surface 110B of the first wafer 110W, and a redistribution structure 140 connected to the through-electrodes 130 may be formed on the polished surface of the first wafer 110W.

After the first wafer 110W′ is transferred to the carrier substrate 410 using an adhesive layer 415, a polishing process of the first wafer 110W may be performed. A desired thickness of the first wafer 110W may be reduced by performing the polishing process up to line PL1′ illustrated in FIG. 6A, and one end of the through-electrodes 130 may be exposed from the non-active surface 110B of the first wafer 110W. Such a polishing process may be performed by a chemical mechanical polishing (CMP) process. In some embodiments, the polishing process may be performed by an etch-back process.

In an embodiment, the redistribution layer 145 may be formed in a multi-level structure. At each level of the multi-level structure, after the insulating layer 141 is formed, a hole may be formed in a via formation position in the insulating layer 141, and the redistribution layer 145 in which a redistribution pattern 142 and a redistribution via 143 are integrated by the same plating process may be formed. A desired redistribution structure 140 may be formed by repeating such a series of processes as many as the number of layers of the multi-level structure.

Next, referring to FIG. 6C, first conductive posts 330 may be formed on the first interconnection structure 120, and a first molded layer 340 surrounding each of the first conductive posts 330 may be formed.

The first conductive posts 330 may be formed on the redistribution structure 140. For example, an opening may be formed in an insulating layer 141 to expose a region of a redistribution layer 145 (a partial region of the redistribution pattern 142), and the first conductive posts 330 may be formed at the exposed region using a plating process.

Next, a first molding member 340′ may be formed on the first interconnection structure 120 to cover the first conductive posts 330, and then the first molding member 340′ may be planarized to expose the first conductive posts 330, to form the first molded layer 340 having an upper surface, substantially coplanar with upper ends of the first conductive posts 330. For example, the first molding member 340′ may include or may be formed of an insulating resin such as EMC.

Next, referring to FIG. 6D, after attaching the first wafer 110W to a first adhesive film 425′, the carrier substrate 410 may be detached from a surface of the first wafer 110W on which the first contact pads 150 are formed. Referring to FIG. 6E, the first wafer 110W may be cut into the first wafer 110W into the plurality of first semiconductor chips 100. Before the cutting process, the non-conductive film 320 may be applied to cover the conductive bumps 310 on the surface on which the first contact pads 150 is formed of the first interconnection structure 120.

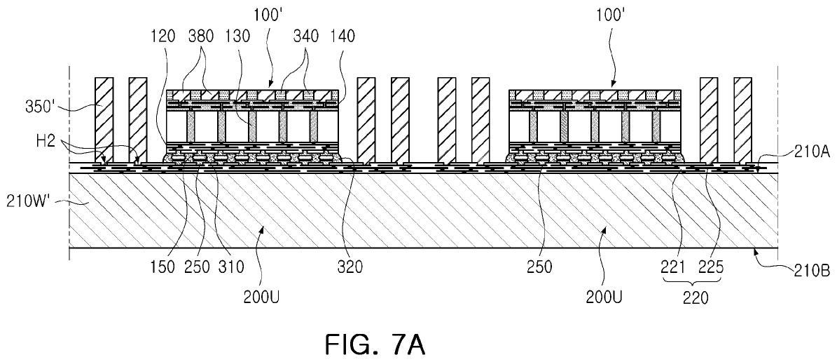

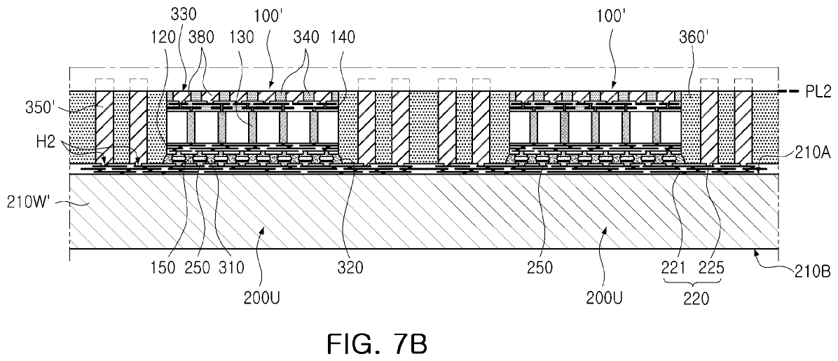

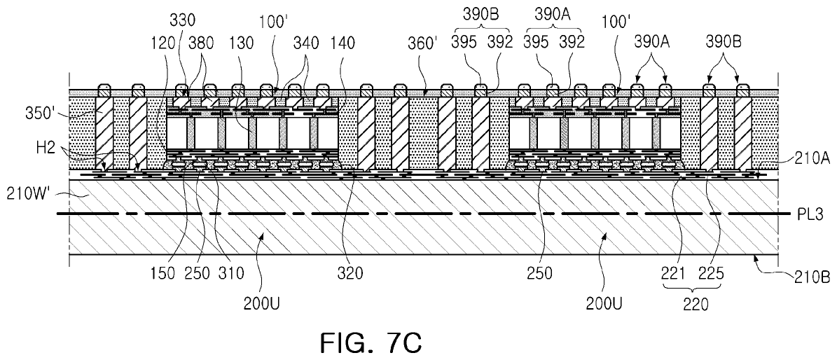

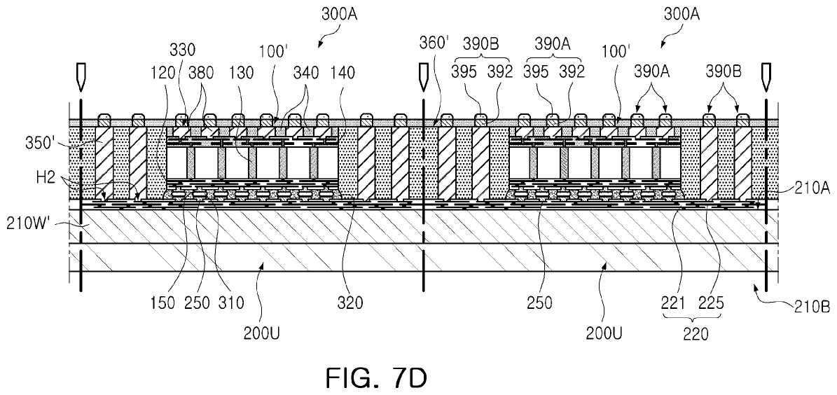

FIGS. 7A to 7D are cross-sectional views for illustrating processes (for manufacturing a final package) in a method of manufacturing the semiconductor package illustrated in FIG. 3. These processes can be understood as processes of manufacturing the semiconductor package 300A illustrated in FIG. 3 using the first semiconductor chip 100′ manufactured in the process of FIG. 6E.

Referring to FIG. 7A, a second wafer 210W at which a plurality of second semiconductor chips 200U are implemented may be prepared, and a plurality of first semiconductor chips 100 and second conductive posts 350 may be disposed on a first region A1 and a second region A2 of a second interconnection structure 220.

As described with reference to FIG. 5A, the second wafer 210W′ may have a second active surface 210A at which devices for the plurality of second semiconductor chips 200U are implemented, and a second non-active surface 210B opposite to the second active surface 210A. The second interconnection structure 220 having a second interconnection layer 225 may be formed on the second active surface 210A of the second wafer 210W′, and the second interconnection layer 225 may be connected to the second active surface 210A (especially devices). Next, second contact pads 250 may be formed on a first region A1 of the second interconnection structure 220

On the second region A2 of the second interconnection structure 220, second conductive posts 350 may be formed to be connected to the second interconnection layer 225. For example, an opening may be formed in a second insulating layer 221 to expose a region of the second interconnection layer 225 (a partial region of a second interconnection pattern 222), and the second conductive posts 350 may be formed at the exposed region using a plating process.

The plurality of first semiconductor chips 100′ manufactured in the process of FIG. 6E may be mounted on the first region A1 of the second interconnection structure 220. When a constant pressure is applied to the plurality of first semiconductor chips 100′, conductive bumps 310 may pass through a non-conductive film 320, to be connected to the second contact pads 250, and first contact pads 150 may be bonded to the second contact pads 250 by the conductive bumps 310, respectively. Then, the non-conductive film 320 may be cured. In this process, the first conductive posts 330 of the first semiconductor chips 100 may be disposed to face upward.

Next, referring to FIG. 7B, a second molded layer 360 (i.e., a second mold layer) may be formed on the second interconnection structure 220. The second molded layer 360 may surround a first molded layer 340, each of the second conductive posts 350, and each of the plurality of first semiconductor chips 100.

The present process may be performed by forming a second molding member 360′ on the second interconnection structure 220 to cover the first molded layer 340 and the second conductive posts 350, and then planarizing the second molding member 360′ to expose the first and second conductive posts 330 and 350. The second molded layer 360 thus obtained may have an upper surface, substantially coplanar with upper ends of the second conductive posts 350, and the upper surface of the second molded layer 360 may be substantially coplanar with an upper surface of the first molded layer 340 and upper ends of the first conductive posts 330. Even though the second molded layer 360 is formed of the same material as the first molded layer 340, since they may be formed by a different process or in a separate process, an interface between the first molded layer 340 and the second molded layer 360 may exist or may be visually identified.

Next, referring to FIG. 7C, a passivation layer 380 disposed on the first molded layer 340 and the second molded layer 360 may be formed, and a plurality of conductive connection structures 390 respectively connected to the second conductive posts 330 and 350 through the passivation layer 380 may be formed. Next, referring to FIG. 7D, a cutting process may be performed to obtain a plurality of semiconductor packages 300A.

In the present embodiment, the passivation layer 380 may be formed on the upper surfaces of the first and second molded layers 340 and 360 without introducing an additional redistribution structure therebetween. Therefore, first and second conductive connection structures 390A and 390B may be provided in a one-to-one corresponding manner, in a region overlapping the first and second conductive posts 330 and 350, respectively. In an embodiment, the first conductive connection structures 390A may be connected to the first conductive posts 330, respectively, and the second conductive connection structures 390B may be connected to the second conductive posts 350, respectively. In an embodiment, each of the first conductive connection structures 390A may vertically overlap a corresponding one of the first conductive posts 330, and each of the second conductive connection structures 390B may vertically overlap a corresponding one of the second conductive posts 350.

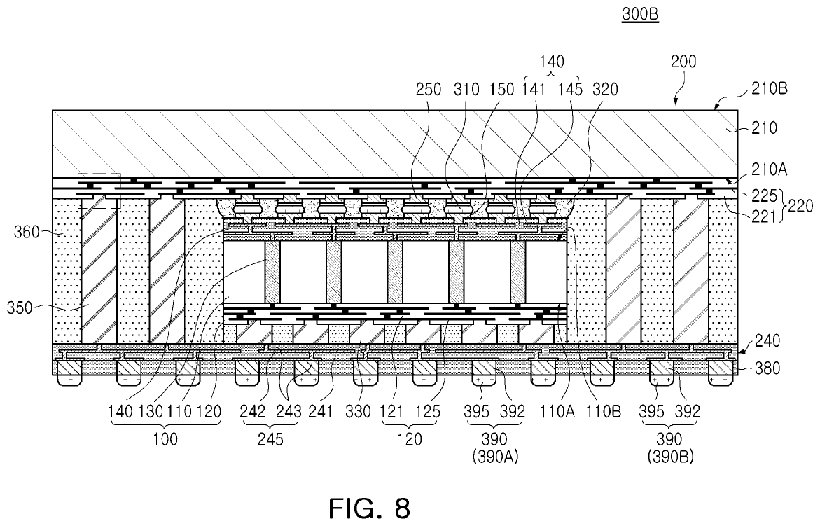

FIG. 8 is a side cross-sectional view of a semiconductor package according to an embodiment.

Referring to FIG. 8, it can be understood that a semiconductor package 300B according to the present embodiment is similar to the embodiment illustrated in FIGS. 1 and 2A to 2C, except that an additional redistribution structure 240 is employed between first and second molded layers 340 and 360 and a passivation layer 380, and arrangement of a conductive connection structure 390 is changed due to the additional redistribution structure 240. Therefore, the description of the embodiment illustrated in FIGS. 1 and 2A to 2C may be combined with description of the present embodiment unless otherwise specifically stated.

The semiconductor package 300B according to the present embodiment may include a second redistribution structure 240 disposed between the first and second molded layers 340 and 360 and the passivation layer 380, in addition to a first redistribution structure 140 disposed on one surface (e.g., a non-active surface) of a first semiconductor chip 100.

The second redistribution structure 240 may include an insulating layer 241 and a second redistribution layer 245 formed on the insulating layer 241. The second redistribution layer 245 may include second redistribution patterns 242, and second redistribution vias 243 for interlayer connection of the second redistribution patterns 242. The second redistribution structure 240 may be connected to first and second conductive posts 330 and 350 to rearrange positions of the conductive connection structures 390 for connection to an external circuit. Similarly to the previous embodiments, the conductive connection structures 390 may include first conductive connection structures 390A respectively connected to the first conductive posts 330, and second conductive connection structures 390B respectively connected to the second conductive posts 350. However, the first and second conductive connection structures 390A and 390B may be rearranged at positions that do not overlap the associated first and second conductive posts 330 and 350.

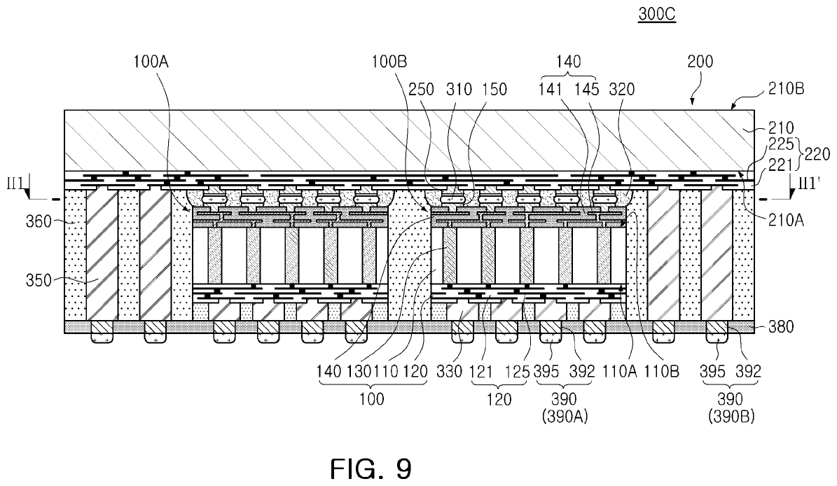

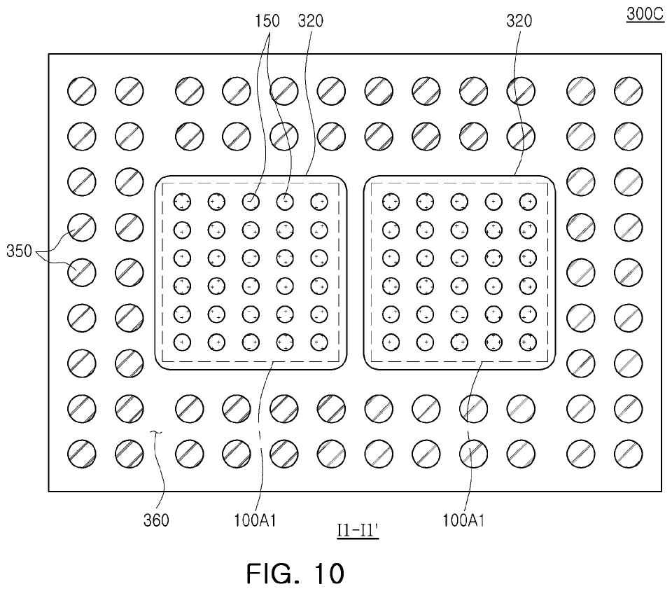

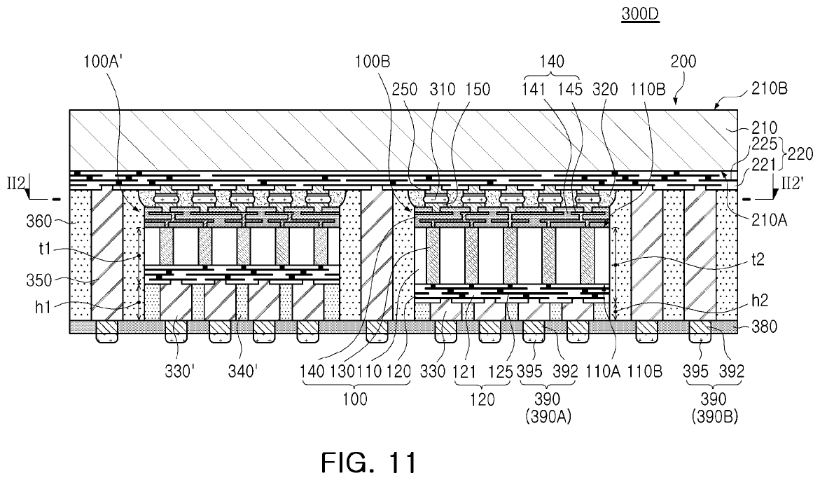

FIG. 9 is a side cross-sectional view of a semiconductor package according to an embodiment, and FIG. 10 is a plan cross-sectional view of the semiconductor package of FIG. 9, taken along line II1-II1′.

Referring to FIGS. 9 and 10, it can be understood that a semiconductor package 300C according to the present embodiment is similar to the embodiment illustrated in FIGS. 1 and 2A to 2C, except that a plurality of first semiconductor chips 100A and 100B are employed. Therefore, the description of the embodiment illustrated in FIGS. 1 and 2A to 2C may be combined with description of the present embodiment unless otherwise specifically stated.

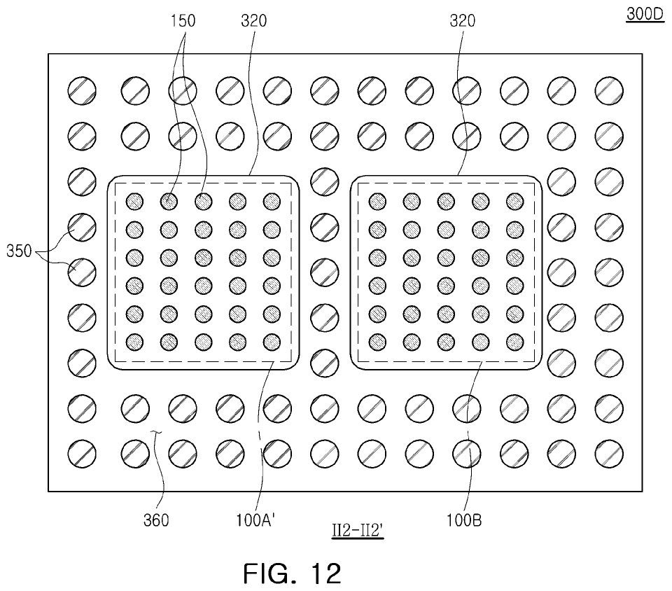

The semiconductor package 300C according to the present embodiment may include a plurality of (e.g., two) first semiconductor chips 100A and 100B arranged on a second semiconductor chip 200 side by side in a horizontal direction. The two first semiconductor chips 100A and 100B may be semiconductor chips manufactured by the processes of FIGS. 4A to 4E, respectively. For example, each of the two first semiconductor chips 100A and 100B may include a redistribution structure 140, and may also individually include first conductive posts 330 and a first molded layer 340 surrounding each of the first conductive posts 330. In the present embodiment, the two first semiconductor chips 100A and 100B are illustrative to have the same shape (and the same thickness). The present inventive concept, however, is not limited thereto. In some embodiments, semiconductor chips having different shapes may be included. This configuration may be illustrated in FIGS. 11 to 13.

FIG. 11 is a side cross-sectional view of a semiconductor package according to an embodiment, and FIG. 12 is a plan cross-sectional view of the semiconductor package of FIG. 11, taken along line II2-II2′.

Referring to FIGS. 11 and 12, it can be understood that a semiconductor package 300D according to the present embodiment is similar to the embodiment illustrated in FIGS. 9 and 10, except that two first semiconductor chips 100A′ and 100B mounted on a second semiconductor chip 200 side by side in a horizontal direction are different from each other, and arrangement of the first semiconductor chips 100A′ and 100B and second conductive posts 350 is asymmetric. Therefore, the description of the embodiment illustrated in FIGS. 9 and 10 together with FIGS. 1 and 2A to 2C may be combined with description of the present embodiment unless otherwise specified.

The semiconductor package 300D according to the present embodiment may include two first semiconductor chips 100A′ and 100B arranged on a second semiconductor chip 200 side by side in a horizontal direction, and the two first semiconductor chips 100A′ and 100B may be different types of chips. For example, the two first semiconductor chips 100A′ and 100B may be configured as chips for implementing different functions. In some embodiments, the two first semiconductor chips 100A′ and 100B may have different sizes, e.g., different areas and/or thicknesses.

Referring to FIG. 11, a first semiconductor chip 100A′ may have a first thickness t1, and a first semiconductor chip 100B may have a second thickness t2, greater than the first thickness t1. In this case, a height h1 of a first conductive post 330′ may be greater than a height h2 of a first conductive post 330. As described above, the first conductive posts 330′ and 330 of the two first semiconductor chips 100A′ and 100B may be formed to have different heights h1 and h2 by compensating for a difference t2−t1 in thickness of the first semiconductor chips 100A′ and 100B to locate a final mounting height at the same level.

Also, in the present embodiment, arrangement of the first semiconductor chips 100A′ and 100B and the second conductive posts 350 may be asymmetric. The second conductive posts 350 may be arranged in different rows (e.g., one left column and two right columns) at opposite corners of the second semiconductor chip 200, and may also be arranged between the two first semiconductor chips 100A′ and 100B. As such, the second conductive posts 350 may be arranged in various manners.

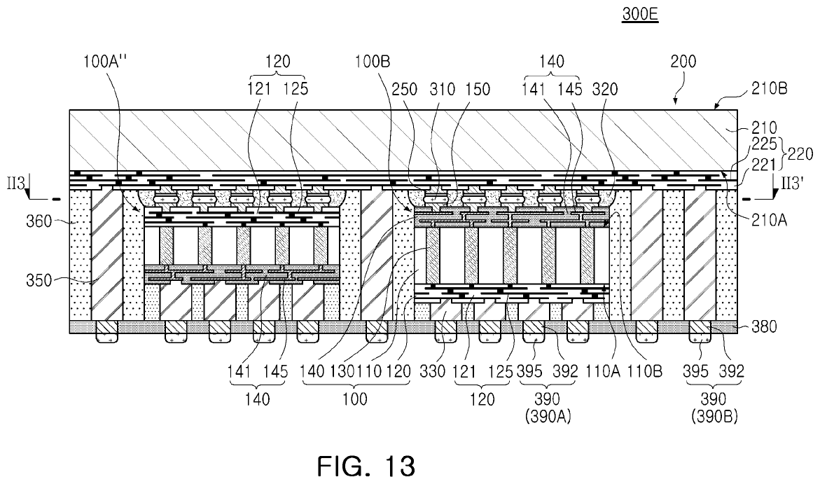

FIG. 13 is a side cross-sectional view of a semiconductor package according to an embodiment.

Referring to FIG. 13, it can be understood that a semiconductor package 300E according to the present embodiment is similar to the embodiment illustrated in FIGS. 11 and 12, except that two first semiconductor chips 100A″ and 100B mounted on a second semiconductor chip 200 side by side in a horizontal direction are different from each other. Therefore, the description of the embodiment illustrated in FIGS. 9 to 12 together with FIGS. 1 and 2A to 2C may be combined with description of the present embodiment unless otherwise specified.

The two first semiconductor chips 100A″ and 100B mounted on the second semiconductor chip 200 may have different types of chips. For example, the two first semiconductor chips 100A″ and 100B may have different areas and/or thicknesses, in a similar manner to the embodiment illustrated in FIG. 11. Referring to FIG. 13, the first semiconductor chip 100A″ on a left side may have an inverted structure to the first semiconductor chip 100B on a right side. For example, the first semiconductor chip 100A″ on the left side may be disposed such that a redistribution structure 140 faces the second semiconductor chip 200, similarly to the first semiconductor chip 100′ illustrated in FIG. 3. First contact pads 150 of the first semiconductor chip 100A″ on the left side may be formed on the first interconnection structure 120. Also, the first semiconductor chip 100A″ on the left side may include a first conductive post 330 and a first molded layer 340, disposed on the redistribution structure 140. As such, any one of a plurality of the first semiconductor chips may be mounted in an inverted structure, unlike other semiconductor chips.

FIG. 14 is a side cross-sectional view of a semiconductor package according to an embodiment.

Referring to FIG. 14, it can be understood that a semiconductor package 300F according to the present embodiment is similar to the embodiment illustrated in FIGS. 1 and 2A to 2C, except that a plurality of first semiconductor chips 100C1, 100C2, 100C3, and 100C4 vertically stacked on a second semiconductor chip 200 are mounted thereon. Therefore, the description of the embodiment illustrated in FIGS. 1 and 2A to 2C may be combined with description of the present embodiment unless otherwise specifically stated.

The semiconductor package 300F according to the present embodiment may include a chip stack 100S including a plurality of first semiconductor chips 100C1, 100C2, 100C3, and 100C4 stacked on a second semiconductor chip 200 in a vertical direction. In the present embodiment, the first semiconductor chips are illustrated as four, but the present inventive concept is not limited thereto, and two or more different numbers of the second semiconductor chips 200 may be included.

Each of the first semiconductor chips 100C1, 100C2, 100C3, and 100C4 may include a first semiconductor substrate 110 having an active surface and an non-active surface, located opposite to each other, a first interconnection structure 120 disposed on the active surface, through-electrodes 130 passing through the first semiconductor substrate 110 and connected to the first interconnection structure 120, and a rear protection layer 160 disposed on the non-active surface. Also, each of the first semiconductor chips 100C1, 100C2, 100C3, and 100C4 may include front contact pads 150A disposed on the first interconnection structure 120, and rear contact pads 150B disposed on the rear protection layer 160, respectively, and the front contact pads 150A and the rear contact pads 150B may be connected with each other by the through-electrodes 130, respectively.

The front contact pads 150A of an uppermost first semiconductor chip 100C1 may be respectively connected to the second contact pads 250 of the second semiconductor chip 200 by conductive bumps 310. A non-conductive film 320 (i.e., an insulating film) surrounding each of the conductive bumps 310 may be disposed between the uppermost first semiconductor chip 100C1 and the second semiconductor chip 200.

Also, a lowermost first semiconductor chip 100C4 may include a redistribution structure 140 disposed on the non-active surface. As described in the previous embodiment, the redistribution structure may include an insulating layer 141 and a redistribution layer 145 formed on the insulating layer 141, and the redistribution layer 145 may include redistribution patterns 142, and redistribution vias 143 for interlayer connection of the redistribution patterns 142. The first contact pads 150 of the first semiconductor chip 100 may be disposed on the redistribution structure 140, and may be electrically connected to the redistribution layer 145.

First conductive posts 330 and a first molded layer 340 surrounding each of the first conductive posts 330 may be formed on the redistribution structure 140. The first molded layer 340 may have an upper surface, substantially coplanar with upper ends of the first conductive posts 330. The first molded layer 340 may have side surfaces, coplanar with side surfaces of the chip stacks 100S.

A second molded layer 360 may be disposed on the second region of the second interconnection structure 220, and may be formed to surround the first semiconductor chip 100 and each of the second conductive posts 350. As illustrated in FIG. 14, the second molded layer 360 may have an upper surface, substantially coplanar with the upper ends of the second conductive posts 350, and the upper surface of the second molded layer 360 may also be substantially coplanar with an upper surface of the molded layer 340 and the upper ends of the first conductive posts 330.

A conductive connection structure 390 employed in the present embodiment may include first conductive connection structures 390A respectively connected to the first conductive posts 330, and second conductive connection structures 390B respectively connected to the second conductive posts 350. As illustrated in FIG. 1, the passivation layer 380 may be formed to contact the upper surfaces of the first and second molded layers 340 and 360 without introducing an additional redistribution structure such as a redistribution layer (e.g., RDL). The first and second conductive connection structures 390A and 390B may be disposed in a one-to-one corresponding manner, in a region overlapping the first and second conductive posts 330 and 350, respectively. In an embodiment, the first conductive connection structures 390A may be connected to the first conductive posts 330, respectively, and the second conductive connection structures 390B may be connected to the second conductive posts 350, respectively. In an embodiment, each of the first conductive connection structures 390A may vertically overlap a corresponding one of the first conductive posts 330, and each of the second conductive connection structures 390B may vertically overlap a corresponding one of the second conductive posts 350.

Although not limited thereto, the first semiconductor chips 100C1, 100C2, 100C3, and 100C4 may be memory devices such as a volatile memory chip and/or a non-volatile memory chip, and the chip stack 100S may be a high bandwidth memory (HBM). Also, the second semiconductor chip 200 may be a control chip for driving a memory device.

According to embodiments, it is possible to provide a semiconductor package and a method of manufacturing the same, having excellent connection reliability between stacked semiconductor chips and improving a degree of precision of a process of a redistribution structure.

Various advantages and effects of the present inventive concept are not limited to the above, and will be more easily understood in the process of describing specific embodiments.

While example embodiments have been illustrated and described above, it will be apparent to those skilled in the art that modifications and variations could be made without departing from the scope of the present inventive concept as defined by the appended claims.

1. A semiconductor package comprising:
a first semiconductor chip including a first semiconductor substrate having a first active surface and a first non-active surface, opposite to each other, a first interconnection structure disposed on the first active surface, through-electrodes passing through the first semiconductor substrate and connected to the first interconnection structure, a redistribution structure disposed on the first non-active surface and connected to the through-electrodes, and first contact pads disposed on the redistribution structure;
a second semiconductor chip including a second semiconductor substrate having a second active surface and a second non-active surface, opposite to each other, a second interconnection structure disposed on the second active surface and having a first region on which the first semiconductor chip is disposed and a second region, different from the first region, and second contact pads disposed on the first region of the second interconnection structure and respectively bonded to the first contact pads;
first conductive posts disposed on the first interconnection structure;
a first mold layer disposed on the first interconnection structure and surrounding each first conductive post of the first conductive posts;
second conductive posts disposed on the second region of the second interconnection structure;
a second mold layer disposed on the second region of the second interconnection structure and surrounding the first semiconductor chip, the first mold layer, and each second conductive post of the second conductive posts;
a passivation layer disposed on the first mold layer and the second mold layer;
first conductive connection structures passing through the passivation layer and respectively connected to the first conductive posts; and
second conductive connection structures passing through the passivation layer and respectively connected to the second conductive posts.

2. The semiconductor package of claim 1,
wherein the first mold layer has an upper surface being coplanar with upper ends of the first conductive posts.

3. The semiconductor package of claim 2,
wherein the second mold layer has an upper surface being coplanar with upper ends of the second conductive posts and the upper surface of the first mold layer.

4. The semiconductor package of claim 1,
wherein an interface between the first and second mold layers is visually identified.

5. The semiconductor package of claim 1,
wherein the first mold layer and the second mold layer comprise different materials.

6. The semiconductor package of claim 1, further comprising:
conductive bumps connecting the first contact pads to the second contact pads.

7. The semiconductor package of claim 6, further comprising:
a non-conductive film disposed between the first semiconductor chip and the second semiconductor chip and surrounding each conductive bump of the conductive bumps.

8. The semiconductor package of claim 1,
wherein each of the first semiconductor chip and the second semiconductor chip comprises a logic chip.

9. The semiconductor package of claim 1, further comprising:
a third semiconductor chip disposed on the first region of the second interconnection structure,
wherein the first and third semiconductor chips are disposed side by side in a horizontal direction on the first region of the second interconnection structure.

10. The semiconductor package of claim 9,
wherein the first and third semiconductor chips have the same thickness.

11. The semiconductor package of claim 9, further comprising:
a third mold layer disposed in a space between the passivation layer and the third semiconductor chip,
wherein the first and third mold layers have different thicknesses,
wherein each of upper surfaces of the first and third mold layers is coplanar with an upper surface of the second mold layer, and
wherein the passivation layer contacts the upper surface of each of the first, second, and third mold layers.

12. The semiconductor package of claim 1,
wherein the first semiconductor chip comprises a plurality of stacked semiconductor chips.

13. The semiconductor package of claim 12,
wherein the plurality of stacked semiconductor chips comprise a memory chip, and the second semiconductor chip comprises a logic chip.

14. The semiconductor package of claim 1,
wherein the passivation layer contacts each of the first and second mold layers.

15. The semiconductor package of claim 1,
wherein the first and second contact pads are arranged in a first pitch, and the second conductive posts are arranged in a second pitch, greater than the first pitch.

16. A semiconductor package comprising:
a first semiconductor chip including a first substrate having a first surface and a second surface, located opposite to each other, and including a redistribution structure located on the first surface, a first interconnection structure disposed on the second surface, through-electrodes passing through the first substrate and connecting the redistribution structure to the first interconnection structure, and first contact pads disposed on the redistribution structure;
first conductive posts disposed on the first interconnection structure and electrically connected to the first interconnection structure;
a first mold layer disposed on the first interconnection structure and having an upper surface, coplanar with upper ends of the first conductive posts;
a second semiconductor chip including a second interconnection structure having a first region on which the first semiconductor chip is disposed and a second region, different from the first region, and second contact pads disposed on the first region of the second interconnection structure and respectively connected to the first contact pads, wherein the first surface of the first semiconductor chip is disposed to face the second interconnection structure;
second conductive posts disposed on the second region of the second interconnection structure and electrically connected to the second interconnection structure;
a second mold layer disposed on the second region of the second interconnection structure, and having an upper surface, coplanar with upper ends of the second conductive posts and the upper surface of the first mold layer;
a passivation layer disposed on the first mold layer and the second mold layer; and
a plurality of conductive connection structures passing through the passivation layer and respectively connected to the first and second conductive posts.

17. The semiconductor package of claim 16, further comprising:
conductive bumps connecting the first contact pads and the second contact pads; and
a non-conductive film disposed between the first semiconductor chip and the second semiconductor chip and surrounding each conductive bump of the conductive bumps.

18. The semiconductor package of claim 16,
wherein the plurality of conductive connection structures comprise first conductive connection structures respectively connected to the first conductive posts, and second conductive connection structures respectively connected to the second conductive posts.

19. The semiconductor package of claim 16,
wherein the first interconnection structure and the second interconnection structure comprise a first interconnection layer and a second interconnection layer, respectively, and
wherein the first conductive posts and the second conductive posts contact the first interconnection layer and the second interconnection layer, respectively.

20. A semiconductor package comprising:
a first semiconductor chip including a first substrate having a first surface and a second surface, located opposite to each other, and including a redistribution structure located on the first surface, a first interconnection structure disposed on the second surface, through-electrodes passing through the first substrate and connecting the redistribution structure to the first interconnection structure, and first contact pads disposed on the first interconnection structure;
first conductive posts disposed on the redistribution structure and electrically connected to the redistribution structure;
a first mold layer disposed on the redistribution structure and having an upper surface, coplanar with upper ends of the first conductive posts;
a second semiconductor chip including a second interconnection structure having a first region on which the first semiconductor chip is disposed and a second region, different from the first region, and second contact pads disposed on the first region of the second interconnection structure and respectively connected to the first contact pads, wherein the second surface of the first semiconductor chip is disposed to face the second interconnection structure;
second conductive posts disposed on the second region of the second interconnection structure and electrically connected to the second interconnection structure;
a second mold layer disposed on the second region of the second interconnection structure, and having an upper surface, coplanar with upper ends of the second conductive posts and the upper surface of the first mold layer;
a passivation layer disposed on the first mold layer and the second mold layer; and a plurality of conductive connection structures passing through the passivation layer and respectively connected to the first and second conductive posts.

21-27. (canceled)
